(19) United States
(12) Patent Application Publication
(10) Pub. No.: US 2021/0111008 A1
(43) Pub. Date: Apr. 15, 2021

(54) METHOD OF DETERMINING CLEANING CONDITIONS AND PLASMA PROCESSING DEVICE

(71) Applicant: TOKYO ELECTRON LIMITED, Tokyo (JP)

(72) Inventor: Shun ITOH, Miyagi (JP)

(21) Appl. No.: 17/060,139

(22) Filed: Oct. 1, 2020

(30) Foreign Application Priority Data
Oct. 9, 2019 (JP) 2019-186290

(51) Int. Cl. H01J 37/32; G01N 21/68; B08B 9/08; B08B 7/00

(52) U.S. Cl. CPC H01J 37/32862; H01J 37/32715; H01L 21/67069; B08B 9/08; B08B 7/0035; G01N 21/68

(57) ABSTRACT

A method of determining cleaning conditions includes: processing a substrate under a substrate processing condition in a chamber, acquiring light emission intensity data by performing cleaning of an interior of the chamber based on cleaning conditions which are different from each other; and performing a step of evaluating the cleaning conditions based on the light emission intensity data, and a step of selecting the cleaning conditions based on the evaluation of the cleaning conditions.

### CROSS-REFERENCE TO RELATED APPLICATION

This application is based upon and claims the benefit of priority from Japanese Patent Application No. 2019-186290, filed on Oct. 9, 2019, the entire contents of which are incorporated herein by reference.

### TECHNICAL FIELD

The present disclosure relates to a method of determining cleaning conditions and a plasma processing device.

### BACKGROUND

For example, a plasma processing device that performs plasma processing on a substrate such as a wafer or the like is known. When the plasma processing is performed, a reaction product is generated and adhered to the interior of a chamber. Therefore, cleaning of the interior of the chamber is carried out.

Patent Document 1 discloses a plasma processing method in which a cleaning recipe is selected and cleaning of a plasma process chamber is performed according to the selected cleaning recipe.

### PRIOR ART DOCUMENTS

[Patent Documents]
Patent Document 1: Japanese laid-open publication No. 2003-277935

### SUMMARY

According to one embodiment of the present disclosure, a method of determining cleaning conditions includes: processing a substrate under a substrate processing condition in a chamber, acquiring light emission intensity data by performing cleaning of an interior of the chamber based on cleaning conditions which are different from each other; and performing a step of evaluating the cleaning conditions based on the light emission intensity data, and a step of selecting the cleaning conditions based on the evaluation of the cleaning conditions.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view illustrating an example of a plasma processing device according to an embodiment of the present disclosure.

FIGS. 2A and 2B are graphs illustrating an example of light emission intensity detected by a detector.

FIG. 3 is a flowchart illustrating a process of determining cleaning conditions in dry cleaning.

FIG. 4 is an example of a graph illustrating detected values of light emission intensities and a fitted function.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments. Like components in each drawing are denoted by like reference numerals and a repeated description thereof will be omitted.

### [Plasma Processing Device]

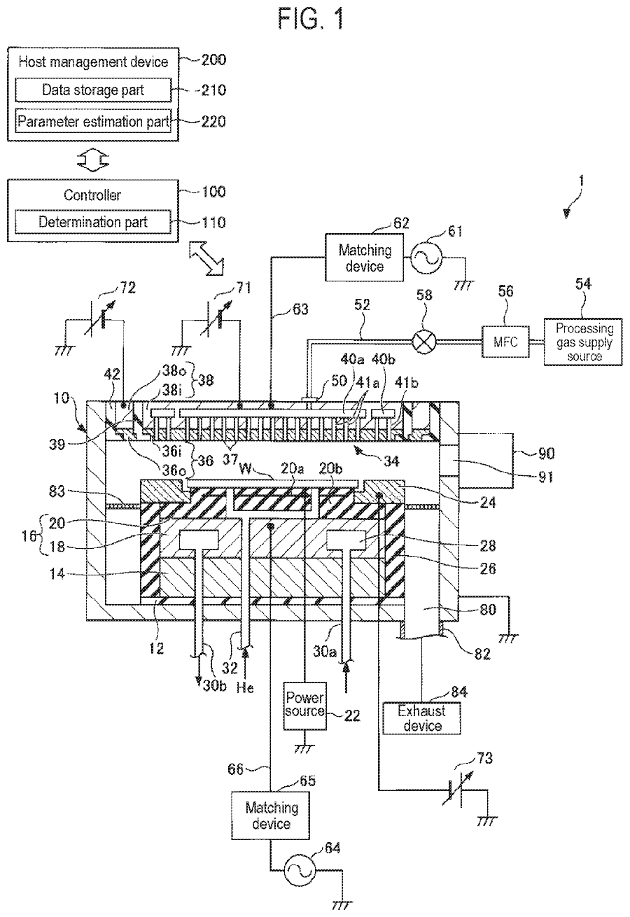

A plasma processing device 1 according to an embodiment of the present disclosure will be described with reference to FIG. 1. FIG. 1 is a schematic cross-sectional view illustrating an example of the plasma processing device 1 according to one embodiment. The plasma processing device 1 according to one embodiment is a capacitively coupled parallel flat plate processing device, and has a chamber 10. The chamber 10 is, for example, a cylindrical vessel made of aluminum whose surface is anodized, and is grounded.

A cylindrical support table 14 is arranged at the bottom of the chamber 10 via an insulating plate 12 made of ceramics or the like. A mounting table 16 is installed on the support table 14. The mounting table 16 has an electrostatic chuck 20 and a base 18, and mounts a wafer W on an upper surface of the electrostatic chuck 20. An annular edge ring 24 made of, for example, silicon, is arranged around the wafer W. The edge ring 24 will also be referred to as a focus ring. The edge ring 24 is an example of an outer peripheral member arranged around the mounting table 16. An annular insulator ring 26 made of, for example, quartz, is installed around the base 18 and the support table 14. In a central portion of the electrostatic chuck 20, a first electrode 20a formed of a conductive film is inserted in an insulating layers 20b. The first electrode 20a is connected to a power source 22. An electrostatic force is generated by a DC voltage applied to the first electrode 20a from the power source 22 so that the wafer W is adsorbed onto a wafer mounting surface of the electrostatic chuck 20. In addition, the electrostatic chuck 20 may have a heater, by which the temperature thereof is controlled.

For example, a ring-shaped or spiral refrigerant chamber 28 is formed inside the base 18. A refrigerant having a predetermined temperature, for example, cooling water, supplied from a chiller unit (not shown) is returned to the chiller unit via a pipe 30a, the refrigerant chamber 28, and a pipe 30b. Since the refrigerant is circulated through such a path, the temperature of the wafer W can be controlled by the temperature of the refrigerant. Furthermore, a heat transfer gas supplied from a heat transfer gas supply mechanism, for example, an He gas, is supplied to a gap between the front surface of the electrostatic chuck 20 and the rear surface of the wafer W via a gas supply line 32. By this heat transfer gas, a heat transfer coefficient between the front surface of the electrostatic chuck 20 and the rear surface of the wafer W is increased, and the temperature of the wafer W is more effectively controlled by the temperature of the refrigerant. In addition, when the electrostatic chuck 20 has the heater, the temperature of the wafer W can be controlled with high responsiveness and high accuracy by heating with the heater and cooling with the refrigerant.

An upper electrode 34 is installed on a ceiling portion of the chamber 10 so as to face the mounting table 16. A plasma processing space is formed between the upper electrode 34 and the mounting table 16. The upper electrode 34 is configured to close an opening of the ceiling portion of the chamber 10 via an insulating shielding member 42. The upper electrode 34 has an electrode plate 36 and an electrode support 38. The electrode plate 36 has an inner electrode plate 36i and an outer electrode plate 36o. The inner electrode plate 36i has a plurality of gas discharge holes 37 formed in a surface thereof facing the mounting table 16, and is made of a silicon-containing material such as silicon, SiC or the like. The outer electrode plate 36o is disposed at the outer side of the inner electrode plate 36i, and is made of a silicon-containing material such as silicon, SiC or the like. An inner electrode support 38i is configured to detachably support the inner electrode plate 36i, and is made of a conductive material, for example, aluminum whose surface is anodized. Inside the inner electrode support 38i, a plurality of gas flow holes 41a and 41b are configured to extend downward from gas diffusion chambers 40a and 40b and communicate with the gas discharge holes 37. The outer electrode support 38o is configured to detachably support the outer electrode plate 36o, and is made of a conductive material, for example, aluminum whose surface is anodized. An insulating shielding member 39 is disposed between the inner electrode plate 36i and the inner electrode support 38i and is disposed between the outer electrode plate 36o and the outer electrode support 38o. Therefore, it is configured so that a voltage can be independently applied to the inner electrode plate 36i and the outer electrode plate 36o.

A gas introduction hole 50 is connected to a processing gas supply source 54 via a gas supply pipe 52. A mass flow controller (MFC) 56 and an opening/closing valve 58 are installed in the gas supply pipe 52 sequentially from the corresponding upstream side at which the processing gas supply source 54 is disposed. A processing gas is supplied from the processing gas supply source 54 and is discharged in a shower shape from the gas discharge holes 37 through the gas supply pipe 52 via the gas diffusion chambers 40a and 40b and the gas flow holes 41a and 41b by controlling the flow rate and opening/closing operation by the mass flow controller 56 and the opening/closing valve 58. Although not shown, it is also configured so that the flow rate of the gas discharged from the gas flow holes 41a and 41b can be independently adjusted.

The plasma processing device 1 has a first high-frequency power source 61 and a second high-frequency power source 64. The first high-frequency power source 61 is a power source which generates a first high-frequency power (hereinafter, also referred to as an “HF power”). The first high-frequency power has a frequency suitable for plasma generation. The frequency of the first high-frequency power is a frequency which falls within a range of, for example, 27 to 100 MHz. The first high-frequency power source 61 is connected to the upper electrode 34 via a matching device 62 and a power supply line 63. The matching device 62 has a circuit for matching the output impedance of the first high-frequency power source 61 with the impedance of a load side (the upper electrode 34 side). In addition, the first high-frequency power source 61 may be connected to the base 18 via the matching device 62.

The second high-frequency power source 64 is a power source which generates a second high-frequency power (hereinafter, also referred to as an “LF power”). The second high-frequency power has a frequency lower than the frequency of the first high-frequency power. If the second high-frequency power is used together with the first high-frequency power, the second high-frequency power is used as a high-frequency power for bias for drawing ions into the wafer W. The frequency of the second high-frequency power is a frequency which falls within a range of, for example, 400 kHz to 13.56 MHz. The second high-frequency power source 64 is connected to the base 18 via a matching device 65 and a power supply line 66. The matching device 65 has a circuit for matching the output impedance of the second high-frequency power source 64 with the impedance of a load side (the base 18 side).

Furthermore, plasma may be generated using the second high-frequency power, i.e., using only the single high-frequency power, without using the first high-frequency power. In this case, the frequency of the second high-frequency power may be a frequency higher than 13.56 MHz, for example, 40 MHz. The plasma processing device 1 may not include the first high-frequency power source 61 and the matching device 62. With this configuration, the mounting table 16 also functions as a lower electrode. The upper electrode 34 also functions as a shower head which supplies a gas.

A first variable power source 71 is connected to the inner electrode support 38i of the upper electrode 34, and applies a DC voltage to the inner electrode plate 36i of the upper electrode 34. A second variable power source 72 is connected to the outer electrode support 38o of the upper electrode 34, and applies a DC voltage to the outer electrode plate 36o of the upper electrode 34. A third variable power source 73 is connected to the edge ring 24, and applies a DC voltage to the edge ring 24.

An exhaust device 84 is connected to an exhaust pipe 82. The exhaust device 84 has a vacuum pump such as a turbo molecular pump or the like, and is configured to exhaust a gas from an exhaust port 80 formed at the bottom of the chamber 10 via the exhaust pipe 82 so as to reduce the internal pressure of the chamber 10 to a desired degree of vacuum. Furthermore, the exhaust device 84 is configured to control the internal pressure of the chamber 10 to be constant while using a value of a pressure gauge (not shown) which measures the internal pressure of the chamber 10.

A baffle plate 83 having an annular shape is installed between the insulator ring 26 and a sidewall of the chamber 10. The baffle plate 83 has a plurality of through-holes and is made of aluminum, in which the surface thereof is coated with ceramics such as Y₂O₃ or the like.

A loading/unloading port (not shown) for loading and unloading the wafer W is installed on the sidewall of the chamber 10. In addition, a gate valve (not shown) for opening and closing the loading/unloading port (not shown) is installed thereon.

A controller 100 which controls the entire operation of the device is installed in the plasma processing device 1. A CPU installed in the controller 100 executes a desired plasma processing such as etching or the like according to a recipe stored in a memory such as an ROM, an RAM or the like. A process time, a pressure (for gas exhaust), the first high-frequency power, the second high-frequency power, a voltage, and various gas flow rates, which are control information of the device for process conditions, may be set in the recipe. In addition, an internal temperature of the chamber (an upper electrode temperature, a chamber sidewall temperature, a wafer W temperature, an electrostatic chuck temperature, or the like), a temperature of refrigerant output from a chiller, or the like may be set in the recipe. Furthermore, this recipe indicating a program or the process conditions may be stored in a hard disk or a semiconductor memory. Alternatively, the recipe may be set at a predetermined position, while being stored in a portable computer-readable storage medium such as a CD-ROM, a DVD or the like, so as to be read.

When performing a predetermined plasma processing such as the plasma etching processing or the like in the plasma processing device 1 having such a configuration, the gate valve (not shown) is opened, and the wafer W is loaded into the chamber 10 via the loading/unloading port (not shown) to be mounted on the mounting table 16, and the gate valve (not shown) is subsequently closed. A processing gas is supplied into the chamber 10 so that the interior of the chamber 10 is exhausted by the exhaust device 84.

The first high-frequency power is applied to the upper electrode 34, and the second high-frequency power is applied to the mounting table 16. A DC voltage is applied to the first electrode 20a from the power source 22 so that the wafer W is adsorbed to the mounting table 16. In addition, a DC voltage may be applied to the upper electrode 34 from the variable power sources 71 and 72. Alternatively, a DC voltage may be applied to the edge ring 24 from the variable power source 73.

The plasma processing such as etching or the like is performed on a target surface of the wafer W by radicals or ions in plasma generated in the plasma processing space.

During the plasma processing of the wafer W, light emitted in the chamber 10 is incident on a detector 90 through a window 91 installed on its sidewall. The detector 90 is, for example, a light emission spectrometer, and is configured to detect light emission intensity having a predetermined bright line spectrum (atomic spectrum) wavelength of plasma light using optical emission spectroscopy (OES). However, OES is an example of a method of monitoring the state of plasma, and the detector 90 is not limited to OES as a use method as long as it can monitor the state of plasma. For example, when etching the wafer W, the detector 90 detects light emission intensity, which is used for end point detection.

### <Cleaning>

When the wafer W is processed, a reaction product (deposit) is adhered to the interior of the chamber 10. Therefore, dry cleaning is performed to remove the reaction product adhered to the interior of the chamber 10 by plasma processing.

In the dry cleaning, for example, a dummy wafer (not shown) is mounted on the mounting table 16 to protect the mounting surface of the mounting table 16, and the reaction product adhered to the inner wall of the chamber 10 is removed by supplying a cleaning gas from the gas supply line 32 to generate plasma by the first high-frequency power source 61.

When the reaction product adhered to the interior of the chamber 10 is exposed to plasma, the reaction product is excited and light-emitted. Therefore, plasma light emission data detected by the detector 90 includes information on the reaction product. That is, the temporal transition of light emission intensity which reflects the remaining reaction product in the chamber 10 can be extracted by extracting a bright-line spectrum wavelength of an element contained in the reaction product by spectroscopy.

However, when the wafer W is processed, the distribution (deposit distribution) of the reaction product adhered to the interior of the chamber 10 and the efficiency distribution of dry cleaning do not match. Then, the cleaning is completed in one region in the chamber 10, and is not completed in other region in the chamber 10. Therefore, when the cleaning is further continued, it becomes overcleaned in the one region, and the wall surface of the chamber 10 is exposed to plasma and damaged. On the other hand, if plasma generation is terminated before the light emission intensity drops to zero, there is a possibility that the reaction product may remain in the other region of the chamber 10. Therefore, cleaning conditions (process parameters or a recipe for cleaning) during the cleaning, which match the deposit distribution with the efficiency distribution of dry cleaning, are required.

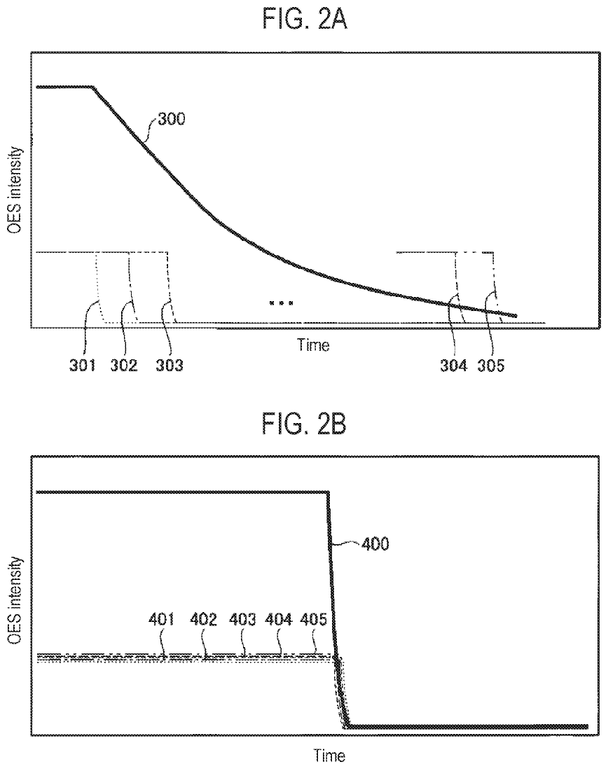

FIG. 2A is a graph illustrating an example of light emission intensity detected by the detector 90. FIG. 2B is a graph illustrating another example of light emission intensity detected by the detector 90. The horizontal axis indicates a time. The vertical axis indicates light emission intensity. Further, light emission intensities detected by the detector 90 are indicated by light emission intensities 300 and 400. In addition, light emission intensities in respective regions in the chamber 10 are schematically indicated by waveforms 301 to 305 and 401 to 405.

In the example shown in FIG. 2A, a case where the deposit distribution and the efficiency distribution of dry cleaning do not match is illustrated. For example, in a region corresponding to the waveform 301, the cleaning is completed before regions corresponding to other waveforms 302 to 305. When the cleaning is completed, the light emission intensity of the waveform 301 is rapidly attenuated. Thereafter, the cleaning is sequentially completed for regions corresponding to the waveforms 302 to 305. When the cleaning is completed, the light emission intensities of the waveforms 302 to 305 are rapidly attenuated. The light emission intensity 300 detected by the detector 90 may be regarded as a sum of the waveforms 301 to 305 of these respective regions. As described above, in the respective regions corresponding to the waveforms 301 to 305, if there is a time difference when the cleaning is completed, temporal characteristics of the light emission intensity 3 detected by the detector 90 become a waveform which is gently attenuated.

In contrast, in the example illustrated in FIG. 2B, a case where the deposit distribution and the efficiency distribution of dry cleaning match is illustrated. In this case, the cleaning is simultaneously completed in regions corresponding to waveforms 401 to 405. When the cleaning is completed, light emission intensities of the waveforms 401 to 405 are rapidly attenuated. The light emission intensity 400 detected by the detector 90 may be regarded as a sum of the waveforms 401 to 405 of these respective regions. Therefore, temporal characteristics of the light emission intensity 400 detected by the detector 90 become a waveform which is rapidly attenuated, compared with the case illustrated in FIG. 2A.

As described above, it is possible to determine the state of a match between the deposit distribution and the efficiency distribution of dry cleaning by monitoring the light emission intensity during the dry cleaning.

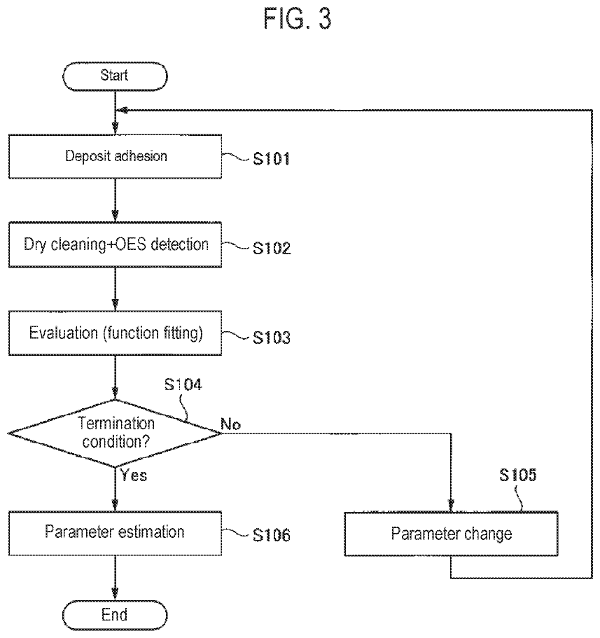

FIG. 3 is a flowchart illustrating a process of determining cleaning conditions in the dry cleaning.

In the present disclosure, the cleaning conditions may include at least one of parameters of an HF power, an LF power, an internal pressure of the chamber 10, a type of gas, a gas flow rate, and a component temperature. In addition, the cleaning conditions may include, for example, at least one of a flow rate of a gas supplied from the inner gas flow hole 41a, a flow rate of a gas supplied from the outer gas flow hole 41b, an application voltage of the first variable power source 71, an application voltage of the second variable power source 72, and an application voltage of the third variable power source 73 in the plasma processing device 1 illustrated in FIG. 1.

At step S101, a deposit is adhered to the interior of the chamber 10. Specifically, the controller 100 performs a desired plasma processing (for example, a film-forming process, an etching process, or the like) on the wafer W according to the substrate processing conditions (recipe). At this time, a reaction product is adhered to the interior of the chamber 10. For example, plasma processing is performed under conditions of an HF power of 300 W, an LF power of 500 W, 50 mTorr, C₄F₆/Ar/O₂=8/1,350/8 sccm, and a lower electrode temperature of 70 degrees C. and a deposit is adhered to the interior of the chamber 10. However, the aforementioned conditions are merely an example, and the present disclosure is not limited thereto.

At step S102, the interior of the chamber 10 is dry-cleaned, and light emission intensity is detected by optical emission spectroscopy (OES). Specifically, the controller 100 performs a dry cleaning process according to set cleaning conditions (parameters). At this time, the controller 100 acquires temporal characteristics of the light emission intensity detected by the detector 90. For example, plasma processing is performed under conditions of an HF power of 500 W, an LF power of 0 W, 100 mTorr, O₂=300 sccm, and a lower electrode temperature of 70 degrees C., and the interior of the chamber 10 is dry-cleaned. However, the aforementioned conditions are merely an example, and the present disclosure is not limited thereto.

At step S103, the cleaning conditions for dry cleaning are evaluated based on the light emission intensity detected at step S102.

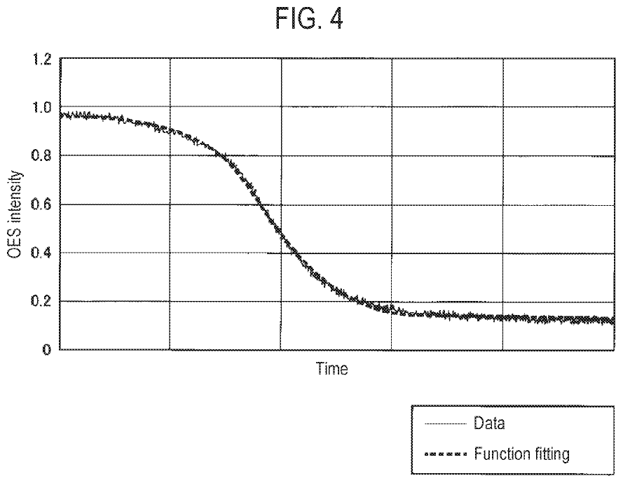

FIG. 4 is an example of a graph illustrating detected values of light emission intensities and a fitted function. Further, in the graph of FIG. 4, the detected values are indicated by a solid line and the fitted function is indicated by a broken line.

A determination part 110 of the controller 100 fits a function to the detected values. As the fitted function, for example, a hyperbolic-tangent function (tan h function) indicated by function expression (1) may be used.

Y=A tan h{B−CT}+D (1)

Where T indicates a time and Y indicates light emission intensity. Further, A, B, C and D are coefficients. The coefficient A is a coefficient related to intensity. The coefficient B is a coefficient related to an offset amount in an x-axis direction (time direction). The coefficient C is a function related to sharpness. As the coefficient C becomes larger, the waveform becomes the sharper (rectangular). As the coefficient C becomes smaller, the waveform becomes gentle. The coefficient D is a coefficient related to an offset amount in a y-axis direction (light emission intensity direction). The determination part 110 obtains the coefficients A to D by fitting the function expression (1) to the detected values.

Then, the determination part 110 uses a value of the coefficient C as an index indicating a match between the deposit distribution and the efficiency distribution of cleaning. That is, as illustrated in FIG. 2B, the waveform becomes shaper (rectangular) and the value of the coefficient C become larger as the deposit distribution and the cleaning efficiency distribution match. As illustrated in FIG. 2A, the waveform becomes gentler and the value of the coefficient C becomes smaller as the deposit distribution and the cleaning efficiency distribution do not match.

Returning to FIG. 3, at step S104, it is determined whether or not a termination condition is satisfied. For example, when the coefficient C is equal to or larger than a predetermined threshold value, the determination part 110 determines that the termination condition is satisfied. Furthermore, the termination condition may be determined based on whether or not step S105, as described hereinbelow, and steps S101 to S103 are repeated a predetermined number of times. If the termination condition is satisfied (Yes at S104), the process of the controller 100 proceeds to step S106. If the termination condition is not satisfied (No at S104), the process of the controller 100 proceeds to step S105.

At step S105, the cleaning conditions (parameters) for dry cleaning are changed.

Then, the process of the controller 100 is returned to step S11, in which the interior of the chamber 10 is again deposited (S10). Subsequently, the dry cleaning and detection of light emission intensity (S102) and the evaluation (S103) are performed using the cleaning conditions (parameters) changed at step S105. Consequently, a plurality of different cleaning conditions can be evaluated.

At step S106, cleaning conditions (parameters) are selected. Specifically, the determination part 110 selects cleaning conditions (parameters) with a high value of the coefficient C.

As described above, according to the plasma processing device 1 of one embodiment, it is possible to determine the suitable cleaning conditions (parameters) for dry cleaning. That is, it is possible to determine the cleaning conditions for dry cleaning which match the deposit distribution and the cleaning efficiency distribution. Thus, it is possible to suppress the damage to the wall surface in the chamber 10 due to overcleaning.

Furthermore, conventionally, as a method for evaluating the cleaning conditions, a method is known in which the chamber 10 is opened after the dry cleaning is performed, and the remaining amount of deposits is directly measured using a film thickness meter or the like. In this regard, according to the plasma processing device 1 of one embodiment, it is possible to evaluate the cleaning conditions for dry cleaning without opening the chamber 10. Thus, it is possible to reduce man-hours required until the evaluation of the cleaning conditions is obtained. In other words, it is possible to increase the number of cleaning conditions to be evaluated. Therefore, since the plurality of cleaning conditions are evaluated and the suitable cleaning conditions can be determined from the result, it is possible to derive the suitable cleaning conditions with high accuracy.

Moreover, it is possible to quantitatively evaluate the cleaning conditions by fitting the function expression (1) and evaluating the coefficient C.

In addition, as illustrated in FIG. 1, the controller 100 may transmit data of a set of the cleaning conditions (parameters) for dry cleaning and the evaluation result to a host management device 200.

The host management device 200 stores the data transmitted from the controller 100 of the plasma processing device 1 in a data storage part 210. Furthermore, the data stored in the data storage part 210 may include data transmitted from another plasma processing device 1. In addition, the host management device 200 has a parameter estimation part 220 which estimates cleaning conditions (parameters) for dry cleaning based on the data stored in the data storage part 210.

The cleaning conditions estimated by the parameter estimation part 220 are transmitted to, for example, the controller 100. The controller 100 may use the cleaning conditions estimated by the parameter estimation part 220 as cleaning conditions when step S102 is first executed. Furthermore, the cleaning conditions changed at step S105 may be used. Thus, the cleaning conditions to be evaluated can be determined based on the evaluation result stored in the data storage part 210. Accordingly, it is possible to reduce man-hours required until suitable cleaning conditions are derived.

While the plasma processing device 1 has been described above, the present disclosure is not limited to the aforementioned embodiment and the like, and various modifications and improvements may be made without departing from the spirit and scope of the present disclosure described in the accompanying claims.

The fitted function is described as using the hyperbolic-tangent function, but the fitted function is not limited thereto and the fitting may be made using any other function.

Furthermore, it has been described that the data is stored in the host management device 200 and the cleaning conditions for dry cleaning are stored based on the stored data, but the present disclosure is not limited thereto. The controller 100 of the plasma processing device 1 may have the functions of the data storage part 210 and the parameter estimation part 220. Thus, it is possible to store and evaluate the data in the plasma processing device 1.

In addition, the host management device 200 may be responsible for the process executed by the determination part 110. The controller 100 executes the dry cleaning according to the cleaning conditions transmitted from the host management device 200, and transmits the light emission intensity data to the host management device 200. The host management device 200 evaluates the coefficient C by fitting a function to the light emission intensity data. With this configuration, it is possible to simplify the function of the controller 100 and to reduce the cost.

Furthermore, the present processing has been described as being used when selecting the cleaning conditions, but the present disclosure is not limited thereto. In the dry cleaning during the operation of the plasma processing device 1, the cleaning conditions may be evaluated by detecting the light emission intensity. Thus, it is possible to detect a mismatch when the deposit distribution and the efficiency distribution of dry cleaning do not match due to aged deterioration of the plasma processing device 1. Moreover, if a mismatch is detected, the cleaning conditions may be again selected by executing the process illustrated in FIG. 3.

According to the present disclosure in some embodiments, it is possible to provide a method of determining cleaning conditions for suitably cleaning an interior of a processing chamber, and a plasma processing device.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of determining cleaning conditions, comprising:
processing a substrate under a substrate processing condition in a chamber,
acquiring light emission intensity data by performing cleaning of an interior of the chamber based on cleaning conditions which are different from each other; and
performing a step of evaluating the cleaning conditions based on the light emission intensity data, and a step of selecting the cleaning conditions based on the evaluation of the cleaning conditions.

2. The method of claim 1, wherein the acquiring the light emission intensity data includes acquiring a temporal transition of light emission intensity having a bright line spectrum wavelength of an element contained in a reaction product generated when the substrate is processed under the substrate processing condition.

3. The method of claim 1, wherein the step of evaluating is performed by fitting a function to the light emission intensity data.

4. The method of claim 3, wherein the function is a tan h function.

5. The method of claim 4, wherein the tan h function is represented by the following formula (1),
Y=A tan h{B−CT}+D (1)
wherein T denotes a time, Y denotes light emission intensity, and A, B, C and D are coefficients, and
wherein the step of evaluating is performed based on the coefficient C of the time T of the tan h function.

6. The method of claim 5, wherein, in the step of selecting, the cleaning conditions having a high value of the coefficient C of the time T of the tan h function are selected.

7. The method of claim 6, wherein the cleaning conditions include at least one of parameters of an HF power, an LF power, a pressure, a type of gas, a gas flow rate, and a component temperature.

8. The method of claim 1, wherein the cleaning conditions include at least one of parameters of an HF power, an LF power, a pressure, a type of gas, a gas flow rate, and a component temperature.

9. A plasma processing device, comprising:
a chamber having a mounting table on which a substrate is mounted;
a high-frequency power source configured to generate plasma;
a detector configured to measure light emission intensity excited by the plasma; and
a controller,
wherein the controller is configured to perform a process, the process comprising:
processing the substrate under a substrate processing condition in the chamber,
acquiring light emission intensity data by generating the plasma and performing dry cleaning in the chamber based on cleaning conditions which are different from each other; and
performing a step of evaluating the cleaning conditions based on the light emission intensity data, and a step of selecting the cleaning conditions based on the evaluation of the cleaning conditions.
